(19) United States
(12) Patent Application Publication
(10) Pub. No.: US 2007/0134920 A1
(43) Pub. Date: Jun. 14, 2007

(54) CU WIRING FORMATION METHOD

(75) Inventors: Shinya Hirano, Tokyo (JP); Yoshimi Sudo, Tokyo (JP); Tetsunori Imaizumi, Kumamoto (JP); Yasuhiro Yoshida, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/556,382

(22) Filed: Nov. 3, 2006

(30) Foreign Application Priority Data
Nov. 11, 2005 (JP) 2005-327718

(51) Int. Cl. H01L 21/44

(52) U.S. Cl. 438/687

(57) ABSTRACT

A Cu wiring formation method comprises the steps of: forming a Cu film on a wafer by plating; subjecting the Cu film to anticorrosive treatment on the surface thereof after the plating; and annealing the Cu film after the anticorrosive treatment.

### BACKGROUND OF THE INVENTION

1. Field of the Invention

The present invention relates to a Cu wiring formation method that is able to satisfactorily suppress defects of a Cu film from occurring without need of any complicated steps at low costs.

2. Background Art

Cu wiring of semiconductor devices is formed by repeating formation of a Cu film by plating and CMP (chemical mechanical polishing). To improve the formability of a Cu film and reliability of a Cu wiring to be formed, a plating composition, plating conditions, annealing conditions after the plating and the like are properly controlled (see, for example, Japanese patent Laid-open No. 2001-345325).

In such Cu wiring formation steps, high temperature annealing causes a great number of defects to occur in the resulting Cu film. The defects occur at the time when water is in contact with the surface of the Cu film after the annealing. To avoid the defects from occurring, there have been proposed a method wherein a Cu film, not annealed, is freshly stacked on the annealed Cu film, a method of inhibiting water from being attached to by use of an improved apparatus, and the like.

The method of stacking a fresh Cu film has raised a problem such that complicated steps have been needed with high costs. Additionally, there has been a concern that a polishing rate considerably lowers and a configuration of finished wiring degrades depending on the type of slurry used. Since a large quantity of water has been used in the CMP step, a difficulty has been involved in satisfactorily suppressing defects from occurring in the Cu film even if attachment of water has been suppressed by use of the improved apparatus.

### SUMMERY OF THE INVENTION

The invention has been made to solve such problems as set out above and has for its object the provision of a Cu wiring formation method capable of satisfactorily suppressing defects from occurring in a Cu film without need of any complicated steps at low costs.

According to one aspect of the present invention, a Cu wiring formation method comprises the steps of: forming a Cu film on a wafer by plating; subjecting the Cu film to anticorrosive treatment on the surface thereof after the plating; and annealing the Cu film after the anticorrosive treatment.

According to the invention, defects in the Cu film can be satisfactorily suppressed from occurring without need of any complicated steps at low costs.

### BRIEF DESCRIPTION OF THE DRAWINGS

FIGS. 1A, 1B are sectional views for explaining the surface of a Cu film.

FIGS. 2A, 2B are sectional views for explaining that water is in contact with the surface of the Cu film.

FIGS. 3A, 3B are sectional views for explaining a Cu wiring formation method according to the first embodiment of the invention.

FIG. 4 is a schematic view showing a method of evaluating a degree of corrosion by contact, with de-ionized water, of Cu films formed under different plating and annealing temperature conditions.

FIG. 5 shows that the results of observation of droplet dropped portions through an optical microscope (×100) after accelerating evaluation, by evaporation of droplet to dryness, on four types of blanket wafers A, B, C and D wherein an impurity concentration in a film and an annealing temperature are changed by film-formation recipe control of plating.

FIG. 6 is a view showing the results of observation of Cu corrosion wherein a droplet is dropped on a Cu film formed under wafer A conditions and subjected to evaporation to dryness in every 1 to 2 minutes.

FIG. 7 is a schematic view showing dipping treatment in DIW carried out as a measure for inhibiting corrosion.

FIG. 8 shows that the results of the comparative evaluation using the same wafer.

FIGS. 9A to 9C are, respectively, views showing the results of a surface elementary analysis by XPS (X-ray photoelectron spectroscopy) using a blanket wafer formed by use of wafer conditions A with respect to a non-treated portion, an evaporated-to-dryness potion and a dipped portion in DIW.

FIG. 10 is a view showing a distribution of Cu defects in case where the evaporation of droplet to dryness is carried out on pattern wafers formed under film-forming conditions A, B, C and D and the wafers are subsequently subjected to CMP polishing.

FIG. 11 is a view showing a distribution of Cu defects after different pre-treatments of pattern wafers formed under film-forming conditions A and B.

FIG. 12A is a graph showing, for comparison, densities of Cu defects relative to pattern wafers formed under film-forming condition A prior to and after various pre-treatments.

FIG. 12B is an enlarged graph of a portion surrounded by the broken lines in FIG. 12A.

FIG. 13A is a graph showing densities of Cu defects prior to and after various pre-treatments in relation to the days from plating/annealing to CMP.

FIG. 13B is an enlarged graph of a portion surrounded by broken lines in FIG. 13A.

FIGS. 14A to 14C are sectional views for explaining a Cu wiring formation method according to the fourth embodiment of the invention.

FIGS. 15A to 15C are sectional views for explaining a Cu wiring formation method according to the fifth embodiment of the invention.

### DETAILED DESCRIPTION OF THE PREFERRED EMBODIMENTS

### First Embodiment

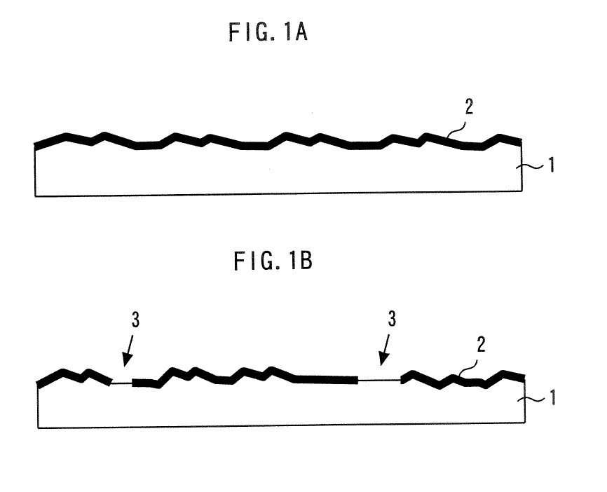

It has been found that such defects as discussed above had occured through local corrosion of a Cu film. The occurrence mechanism of local corrosion is illustrated below. Initially, as shown in FIG. 1A, when the surface of a clean Cu film 1 is exposed to air, a uniform oxide film 2 having a thickness of several nm to several tens of nm is formed on the surface of the Cu film 1. Next, the Cu film 1 is annealed at high temperatures, whereupon, as shown in FIG. 1B, the oxide film becomes non-uniform in the thickness thereof, thereby forming thin portions 3 in the oxide film 2. Although the reason for this is not clearly known, it is assumed that this is ascribed to the deformation of the oxide film accompanied by the deformation of the Cu film such as an enlargement in grain size of Cu and also to the redox reaction of Cu, and the like.

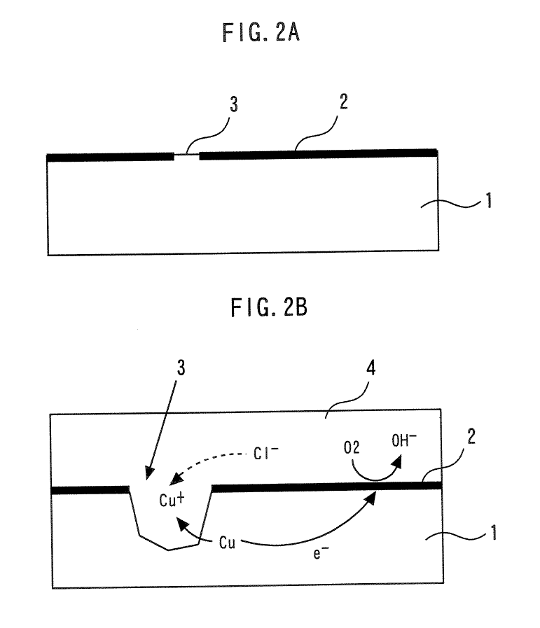

The case where water is in contact with the surface of a Cu film is now described. As shown in FIG. 2A, an oxide film 2 is formed on a surface of a Cu film 1, and a thin portion 3 exists in the oxide film 2. Next, as shown in FIG. 2B, when water 4 is in contact with the surface of the Cu film 1, the portion where the oxide film 2 is properly formed is such that the contact between oxygen dissolved in the contacted water and the Cu film is suppressed. Thus, no oxidation reaction of the Cu film 1 proceeds, under which a reduction reaction of oxygen, which corresponds to the oxidation reaction of the Cu film 1, occurs.

On the other hand, the oxidation reaction of the Cu film 1 occurs at the thin portion 3 of the oxide film 2, so that local corrosion (pitting corrosion) proceeds. At this portion, impurity ions, such as a chlorine ion, gather or oxidation proceeds, for which a oxide film is unlikely to be formed. Accordingly, the oxidation reaction of the Cu film 1 continuedly proceeds. This local corrosion permits the oxidation reaction to occur as concentrated at a minute spot or spots, so that defects are initiated within a short time.

The occurrence of the local corrosion is greatly influenced by, aside from the non-uniformity of the oxide film, the type of substance contained in water to contact therewith. Where water in contact with the surface of the Cu film contains an ionic impurity, electric conductivity of water becomes high and thus, local corrosion is accelerated. In particular, in case where the impurity is made of a chlorine ion or a substance forming a soluble chelate along with Cu, the formation of an oxide film on the surface of the Cu film is impeded, which leads to the likelihood of causing local corrosion to occur. For the impurity, mention is made not only of ones that are contained in water prior to contact with the Cu film, but also ones that are dissolved out from the Cu film or oxide film. Moreover, for the occurrence of local corrosion, the presence of an oxidizing agent is essential. Such an oxidizing agent includes, aside from oxygen dissolved in from air, hydrogen peroxide contained in a CMP slurry and the like.

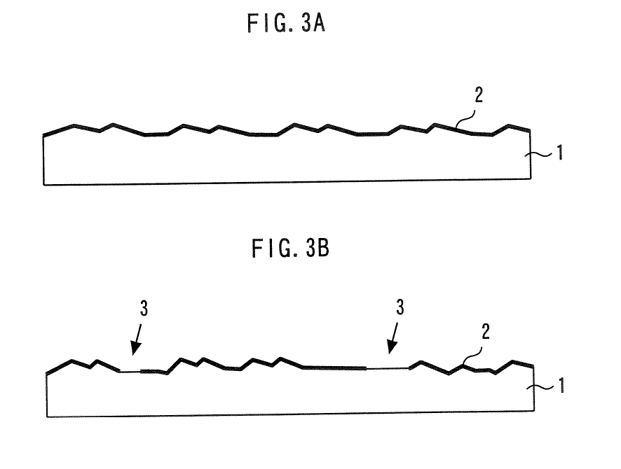

As stated hereinabove, the defects in the Cu film occur through local corrosion. A Cu wiring formation method according to the first embodiment of the invention, which has been made so as to suppress the defects from occurring in the Cu film, is now described. Initially, a Cu film is formed on a wafer by electronic plating procedure or electroless plating procedure, using various plating solutions. Next, as shown in FIG. 3A, the surface of the Cu film 1 is subjected to anticorrosive treatment. Thereafter, as shown in FIG. 3B, the Cu film 1 is subjected to high-temperature annealing at 90° C. or higher in a non-oxidative gas such as N₂, argon, CO₂ or the like or in a reducing gas such as a gas mixed with H₂. The coverage of such a clean surface of the Cu film 1 with an anticorrosive is able to suppress the growth of an oxide film 2. The amount of a non-uniform oxide film formed by the subsequent high-temperature annealing can be reduced, thereby enabling the occurrence of defects to be suppressed or inhibited.

For the anticorrosive, there can be used various types of aliphatic or aromatic hydrocarbons whose structures contain an oxygen atom, a nitrogen atom or sulfur atom therein. Especially, the use of hydrocarbons, which have a polar group such as a carboxyl group, an amino group or the like and whose solubility in water ranges about 0.5 wt % to 70 wt % at room temperature, ensures an appropriate anticorrosive performance in the method of the invention.

The anticorrosive treatment is carried out by bringing the surface of the Cu film into contact with such a compound as mentioned above. The compound may be contacted in the form of a mixture with water, an organic solvent or the like, or may be contacted in a manner of contacting a vapor of the compound. In either case, it is desirable that no oxidizing agent such as oxygen or the like be contained in the solution or vapor. Where the treatment is carried out under conditions where an oxidizing agent is contained, an oxide film may be formed during the treatment, or an anticorrosive layer formed may become thick, thereby causing local corrosion to occur after the high-temperature annealing, like the oxide film.

In order that the oxide film is made as thin as possible, it is preferred that the anticorrosive treatment is carried out within 24 hours after the plating, more preferably within 6 hour. If the anticorrosive treatment is performed after a lapse of 24 hours, an oxide film is formed at some level of thickness during the treatment. Thus, it is not possible to reliably suppress defects from occurring after the high-temperature annealing. Moreover, if wafers after plating are stored under conditions where an oxide is liable to grow for some sort of trigger, there is the possibility that defects occur within 24 hours. In this connection, however, with the anticorrosive treatment within 6 hours, the occurrence of defects can be substantially reliably suppressed within a range of ordinary manufacturing conditions.

As set out hereinabove, when an amount of an oxide film prior to the high-temperature annealing is lessened, a non-uniform oxide film is prevented from forming on the surface of the Cu film upon the high-temperature annealing. Accordingly, the occurrence of defects by local corrosion of the Cu film can be satisfactorily suppressed without need of any complicated steps at low costs.

### Second Embodiment

In the Cu wiring formation method according to the second embodiment of the invention, after formation of the Cu film on a wafer by plating, the wafer is stored in a non-oxidative atmosphere. The non-oxidative atmosphere means the state where an amount of oxygen is small and contains much gas such as, for example, nitrogen, argon or CO₂ gas. This permits an oxide film existing on the Cu surface to be made as small as possible at the time of the high-temperature annealing and thus, similar effects as in the first embodiment can be attained. Moreover, ambient moisture during the storage can be reduced in amount.

### Third Embodiment

In the Cu wiring formation method according to the third embodiment of the invention, after formation of the Cu film on a wafer by plating, an oxide film formed on the surface of the Cu film is removed. The removal of the oxide film can be performed by rinsing with an acidic or alkaline aqueous solution.

The acidic aqueous solution should preferably be an aqueous solution having a pH of not higher than 5. In this case, for example, there may be used aqueous solutions of inorganic acids such as sulfuric acid, hydrofluoric acid, nitric acid, boric acid, phosphoric acid, carbonic acid and the like and organic acids such as formic acid, acetic acid, oxalic acid, citric acid, lactic acid, succinic acid, fumaric acid, malic acid, tartaric acid, maleic acid, benzoic acid, benzenesulfonic acid and the like. Those other than these acids indicated above may also be used so far as they are soluble in water.

On the other hand, the alkaline aqueous solutions should preferably be aqueous solutions having a pH of not lower than 9. For instance, although alkaline aqueous solutions of ammonia or various types of ammonium salts are preferred, aqueous solutions of salts of alkali metals such as potassium, magnesium and the like and alkali earth metals are also usable.

The aqueous solution may be mixed with an organic solvent such as an alcohol or the like or may be admixed with various types of surface active agents. In addition, an oxide film may be reduced by use of a reducing agent. Various types of reducing agents may be used and some effects may be attained when using compounds such as hydrazine, ascorbic acid, hydroquinone and the like, hydrogen compounds such as HI, H₂S and the like, CO, SO₂ and the like.

The oxide film may be removed by sputtering or the like without use of a solution. Moreover, the oxide film may be removed by an electrochemical method. More particularly, a wafer is immersed in water, followed by application of a reduction potential to the Cu film so as to reduce the surface thereof. This treatment may be effected in the plating step or rinsing step.

The interval between the oxide film removing step and the high-temperature annealing should favorably be short in time. The high-temperature annealing should preferably be carried out within 24 hours after removal of the oxide film, more preferably within 6 hours. If the time interval is longer than 24 hours, an oxide film with some level of thickness is formed, so that defects after the high-temperature annealing cannot be reliably suppressed.

The anticorrosive treatment may be effected after removal of the oxide film. In this case, the anticorrosive treatment should preferably be carried out within 24 hours after the removal of the oxide film, more preferably within 6 hours. The wafer after the removal of the oxide film may be stored in a non-oxidative atmosphere.

### Fourth Embodiment

Prior to illustration of the Cu wiring formation method according to the fourth embodiment of the invention, test results on which this method is based are described.

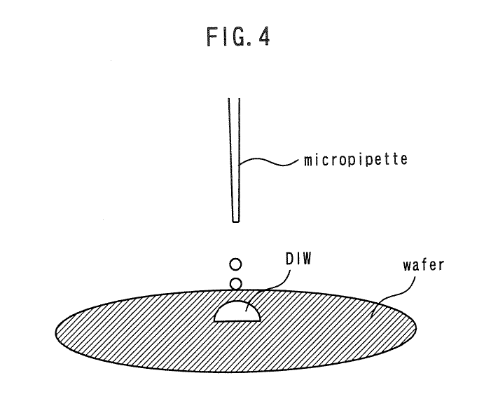

FIG. 4 is a schematic view showing a method of evaluating a degree of corrosion by contact, with de-ionized water, of Cu films formed under different plating and annealing temperature conditions. De-ionized water (DIW) is weighed by means of a micropipette and is dropped on a wafer surface on which a Cu film has been formed, and is naturally dried. The term “a droplet is dropped and naturally dried” is defined as “evaporation of droplet to dryness, or merely as evaporation-to-dryness” herein and whenever it appears hereinafter. This micropipette is attached to a stage that is movable in X and Y axes, and a contact angle measuring system is used herein. The wafer used is a blanket wafer and a pattern wafer, respectively. In the latter case, when a drop position is designated, the evaluation on accelerating corrosion at the designated position can be made, along with the evaluation of different types of defects of Cu after polishing.

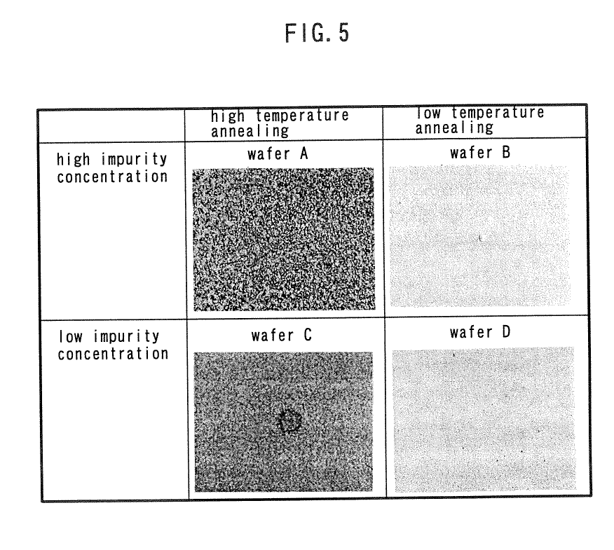

In FIG. 5, there are shown the results of observation of droplet dropped portions through an optical microscope (×100) after accelerating evaluation, by evaporation of droplet to dryness, on four types of blanket wafers A, B, C and D wherein an impurity concentration in a film and an annealing temperature are changed by film-formation recipe control of plating. As shown in the figure, a higher impurity concentration and a higher annealing temperature are more liable to leave traces of evaporated-to-dryness portions. The observation of this site through an optical microscope reveals clear, black-spot Cu corrosion through the low power thereof, along with differences in degree an density of the spots depending on the type of wafer. It has been confirmed that morphology is worsened in the order of wafers of A>>C, B>>D. In view of the results of this evaluation, it has been found that the evaporation-to-dryness treatment accelerates Cu corrosion, and a high surface impurity concentration of plating and high annealing temperature respectively result in higher corrosiveness. It has also been found that a temperature contributes to the annealing treatment more greatly than that type of the gas. Evaluation is now advanced primarily on the conditions of wafer A (of a high impurity concentration and high temperature annealing) that are the most corrosive conditions.

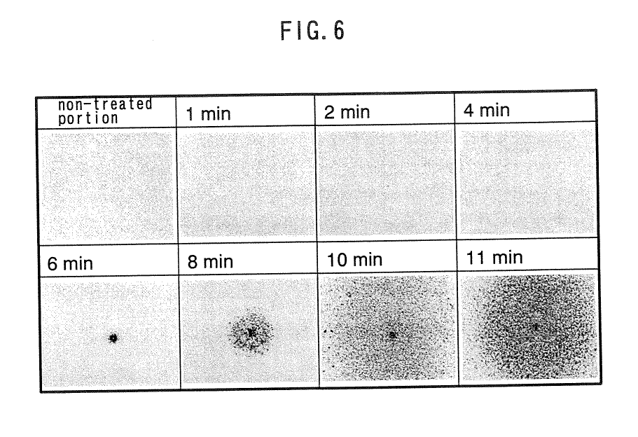

FIG. 6 is a view showing the results of observation of Cu corrosion wherein a droplet is dropped on a Cu film formed under wafer A conditions and subjected to evaporation to dryness in every 1 to 2 minutes. The evaluation was made from the shortest time of 1 minute to the longest time at 11 minutes, under which simultaneously with a residence time of 1 minute of a finally dropped droplet, rinsing with DIW and drying were carried out. At this stage, an initially dropped droplet (with residence time of 11 minutes) was not fully dried. The dropped portion was observed through an optical microscope (by a magnification of 50). When compared with a non-treated portion, no occurrence of a black spot was found before about 4 minutes and no deterioration of morphology was recognized. In this connection, however, after a lapse of 6 minutes, occurrence of black spot-shaped corrosion was confirmed, and it was also confirmed that a longer time tended to increase both the number and size of black spots.

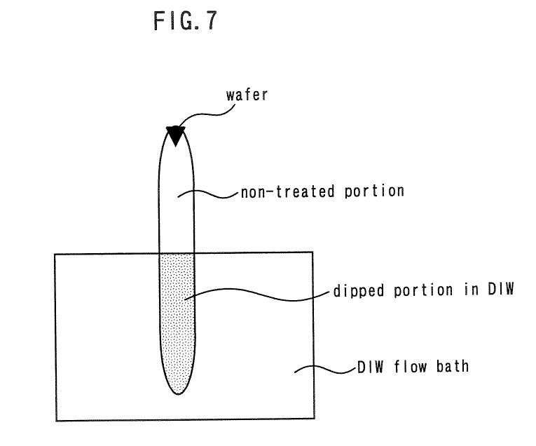

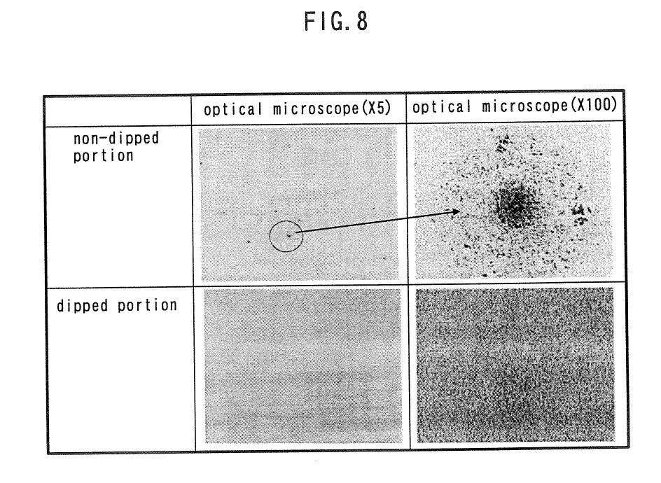

FIG. 7 is a schematic view showing dipping treatment in DIW carried out as a measure for inhibiting corrosion. This treatment was carried out for the purpose of removing a soluble impurity from a plated annealed Cu surface. The dipping treatment in DIW was effected by use of a batchwise running water bath vessel ensuring a satisfactory flow velocity and flow rate. The half of a blanket wafer with a wafer A film is dipped in DIW, and evaluation on the evaporation of droplet to dryness was made relative to a non-treated portion. The results of the comparative evaluation using the same wafer are shown in FIG. 8. Where the evaporation of droplet to dryness on the non-dipped portion was carried out, a plurality of black spot-shaped Cu corrosion were confirmed. On the other hand, where the evaporation of droplet to dryness on the dipped portion was carried out, no trace per se at the evaporated-to-dryness portion was recognized. When the portion was optically inspected in detail, neither black spot corrosion nor deterioration of morphology was found at the non-dipped portion. From these results, it was found that Cu corrosion could be lowered when the dipping treatment in DIW was performed.

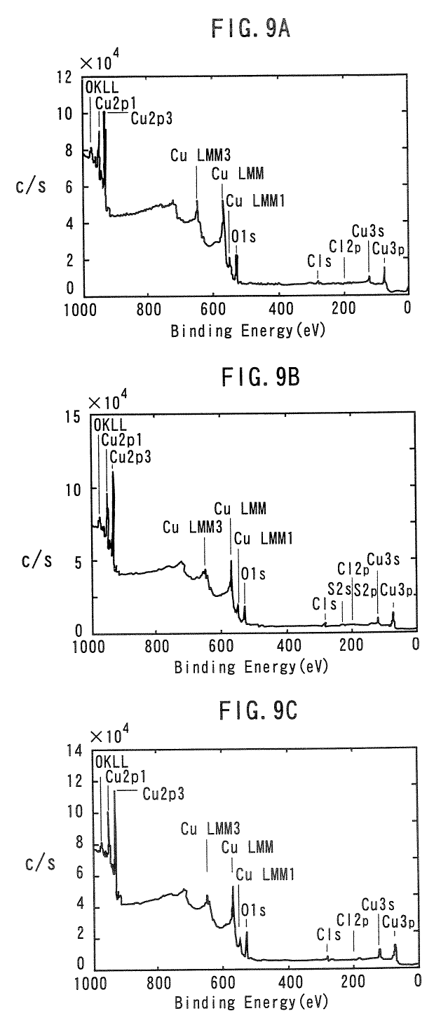

FIGS. 9A to 9C are, respectively, views showing the results of a surface elementary analysis by XPS (X-ray photoelectron spectroscopy) using a blanket wafer formed by use of wafer conditions A with respect to a non-treated portion, an evaporated-to-dryness potion and a dipped portion in DIW.

For comparison, evaluation by XPS was made on non-treated portions under wafer conditions B (high impurity concentration and low annealing temperature) and wafer conditions C (low impurity concentration and high annealing temperature) both of which ensure a less degree of corrosion than wafer conditions A, and also under wafer conditions D (low impurity concentration and low annealing temperature) that are most unlikely to cause corrosion, with the results being summarized in Table 1 below.

TABLE 1

| | Evaluated | Concentration | Annealing | | | | | |
|---|---|---|---|---|---|---|---|---|
| Wafer | portion | of impurity | temperature | Cls | OlS | S2p | Cl2P | Cu2P |
| A | Non-treated | high | high | 13.9 | 34.0 | — | 0.7 | 51.4 |
| | portion | | | | | | | |
| A | DIW droplet | high | high | 13.6 | 32.0 | 1.2 | 1.3 | 51.9 |
| | dropped | | | | | | | |
| | portion | | | | | | | |
| A | Dipped | high | high | 13.9 | 33.1 | — | — | 53.0 |
| | portion | | | | | | | |
| | in running | | | | | | | |
| | water | | | | | | | |
| B | Non-treated | high | low | 15.1 | 32.5 | — | 0.2 | 52.2 |
| | portion | | | | | | | |
| C | Non-treated | low | high | 14.2 | 34.4 | — | 0.3 | 51.2 |
| | portion | | | | | | | |
| D | Non-treated | low | low | 13.7 | 33.4 | — | — | 52.9 |
| | portion | | | | | | | |

As shown in Table 1, Cl was detected from the non-treated portions of the wafers other than that obtained under wafer conditions D (low impurity concentration and low annealing temperature). The conditions arranged in the order of from high to low Cl concentrations are as follows: (1) wafer conditions A (high impurity concentration and high annealing temperature); (2) wafer conditions C (low impurity concentration and high annealing temperature); and (3) wafer conditions B (high impurity concentration and low annealing temperature). It was found that these results were in coincidence with the order of high Cu corrosion. In wafer A, a higher concentration of Cl was detected at the evaporated-to-dryness portion than at the non-treated portion, and non-detected S was freshly detected. Moreover, neither Cl nor S was detected in wafer A with respect to the portion where dipping treatment in running water was carried out.

From these results, it has been elucidated that the mechanism of Cu corrosion can be illustrated by the occurrence of local corrosion in which Cl and S take part and that the reason why corrosiveness is of dependence on plating conditions is due to the correlation between the plating conditions and a Cl or S concentration. It will be noted that where evaporation-to-dryness is carried out, a water-soluble impurity is locally dissolved during the course of pure water contacting with and drying on the Cu surface in the form of a droplet. This causes a local ion concentration to increase, the pH to be lower and electric conductivity to become higher, thereby causing local corrosion to proceed acceleratedly.

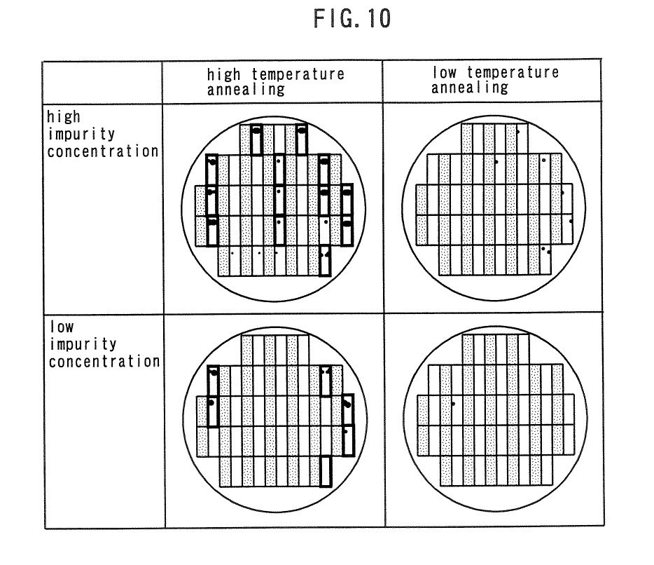

FIG. 10 is a view showing a distribution of Cu defects in case where the evaporation of droplet to dryness is carried out on pattern wafers formed under film-forming conditions A, B, C and D and the wafers are subsequently subjected to CMP polishing. In the figure, sites, each enclosed with thick lines, mean portions where Cu defects occur due to the contact of water prior to the evaporation-to-dryness treatment and CMP polishing. In this evaluation, the evaporation-to-dryness is carried out at three portions of the center of the wafer. Moreover, the density of Cu defects within the enclosure is not uniform, and an enclosure is added even at a portion where only one Cu defect is observed. In an ordinary treatment using a pattern wafer, it has been confirmed that a higher impurity concentration and a higher annealing temperature result in a higher degree of corrosion, like the results shown in FIG. 5.

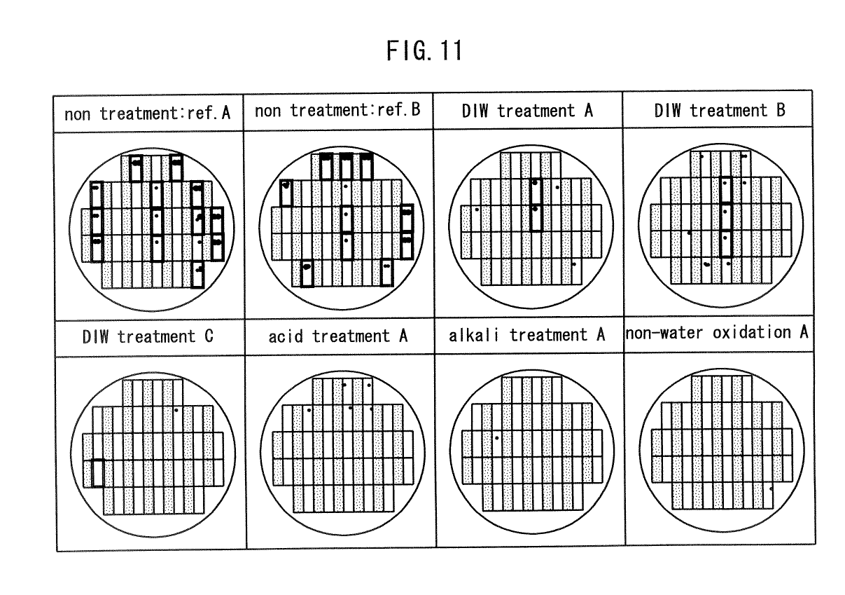

FIG. 11 is a view showing a distribution of Cu defects after different pre-treatments of pattern wafers formed under film-forming conditions A and B. After the pre-treatments, accelerated evaluation of Cu corrosion using the same evaporation-to-dryness treatment was made. Subsequently, after ordinary CMP polishing, defect inspection was performed. Storage ranging from plating/annealing to CMP was made within two days. With non-treated wafers, corrosion occurs throughout the wafers although Cu defects vary in number to some extent.

DIW treatment A carries out dipping treatment of a wafer in a running water vessel as shown in FIG. 7. As a result of the treatment, an effect of inhibiting Cu defects was confirmed although not complete. It will be noted that this method shows a tendency to lower the effect as wafers increase in number. This is assumed for the reason that an ion concentration in pure water increases and a removal efficiency of an impurity on the wafer surface is low. In addition, there is a concern that only a flow rate of running water, temperature and time are factors which can be under control of the method and a throughput is lower than that of a batchwise process.

DIW treatment B carries out DIW rinsing by use of a spin rinsing method. This treatment is able to arbitrarily improve surface substitution efficiency by invariable feed of clean DIW, a rinsing efficiency that is higher than with the case of dipping treatment, and the control of the wafer with respect to the number of revolutions and the flow rate. The results of the treatment reveal that the effect is remarkably improved over the DIW treatment A. It is to be noted that as the substitution efficiency increases, the incorporation of dissolved oxygen in the atmosphere becomes conspicuous and thus, care should be paid to corrosion on the Cu surface. The number of revolutions of the wafer is set at as low as 100 r.p.m. to 1000 r.p.m. in the spin rinsing treatment and the flow rate of DIW dropped from a nozzle is set at 0.1 ml/minute to 2 ml/minute.

DIW treatment C carries out rinsing treatment by use of DIW in which CO₂ is dissolved to saturation in treatment B. The results of this treatment reveal that Cu defects can be inhibited at evaporated-to-dryness portions. According to this treatment, in addition to the improved solubility of surface impurities that is an effect of DIW treatments A and B, the pH lowers in a slight degree owing to the use of the CO₂-dissolved water. Therefore, an etching effect of the Cu oxide film can be expected although the etching rate is considered low. Because CO₂ is dissolved to saturation in the molecular form, the Cu corrosion ascribed to the dissolution of oxygen that is a concern in the treatment B is inhibited. Thus, improvements in treating efficiency and throughput such as increasing the number of revolutions and the flow rate can be expected.

As stated hereinabove, the effect of suppressing Cu defects by DIW treatments A to C has been confirmed. The expected effect is in the order of C>B>A. Although the effect of removing surface impurities is attained, these treatments cannot inhibit local corrosion based on the non-uniformity in thickness of a natural oxide film on the surface of a Cu film as described in detail hereinafter.

Acid treatment A is DHF treatment. As a result of this treatment, Cu defects could be completely inhibited over the entire surface of a wafer including evaporated-to-dryness portions. This is considered for the reason that the Cu oxide film is removed by means of DHF to permit pure Cu to be exposed and thus, corrosion ascribed to a natural oxide film on the surface is inhibited. In this treatment, there is a concern about etching of an oxide film on the back side of a wafer, so that it is necessary to carry out a surface treatment according to a spin treatment without use of a brush.

Alkali treatment A is carried out by using strongly alkaline TMAH (tetramethylammonium hydroxide). In this treatment, Cu defects could be fully inhibited over the entire surface of a wafer including evaporated-to-dryness portions. An area of Cu corrosion is described in pH-redox potential map of Pourbaix. For instance, with a H₂O system, Cu is dissolved in the form of CuO₂⁻ ions in an alkaline region. To cope with this, the pH in this treatment was so set that pH=12 by the pH adjustment caused by dilution of Cu. As a result, in addition to the capability of surface impurity dissolution that is higher than with DIW treatment, the oxide film can be dissolved without dissolution of Cu. In this way, corrosion ascribed to the surface impurity and natural oxide film can be inhibited.

Non-aqueous treatment A is a low temperature plasma O₂ ashing treatment. As a result of the treatment, an effect of suppressing Cu defects that is equal to or better than the effects attained by the acid treatment and the alkali treatment could be confirmed. This is assumed for the reason that CuO which is uniform chemically and in thickness is formed owing to the removal of impurities by radical impact on the surface and the O₂ ashing and thus, functions as a good passivation film.

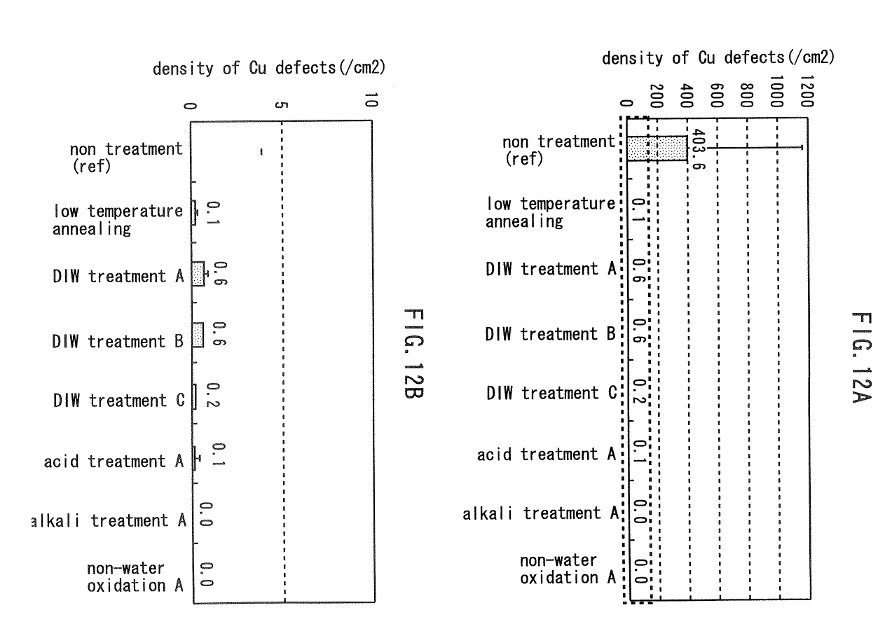

FIG. 12A is a graph showing, for comparison, densities of Cu defects relative to pattern wafers formed under film-forming condition A prior to and after various pre-treatments. FIG. 12B is an enlarged graph of a portion surrounded by the broken lines in FIG. 12A. All of these evaluations were made on the wafers having subjected to the evaporation of droplet to dryness/CMP treatment within two days of plating and annealing. From this graph, it was revealed that with the non-treated case, although Cu defects occurred in large number as a result of the evaporation-to-dryness, the density of Cu defects could be considerably reduced when various pre-treatments were each carried out prior to the evaporation-to-dryness. Especially, it has been found that the density of Cu defects could be reduced to substantially zero according to the acid treatment, alkali treatment and non-aqueous treatment. It has also been found that DIW treatments are poorer in effect than the above-indicated treatments, among which the treatment with CO₂ dissolved water exhibits an effect similar to the latter treatments.

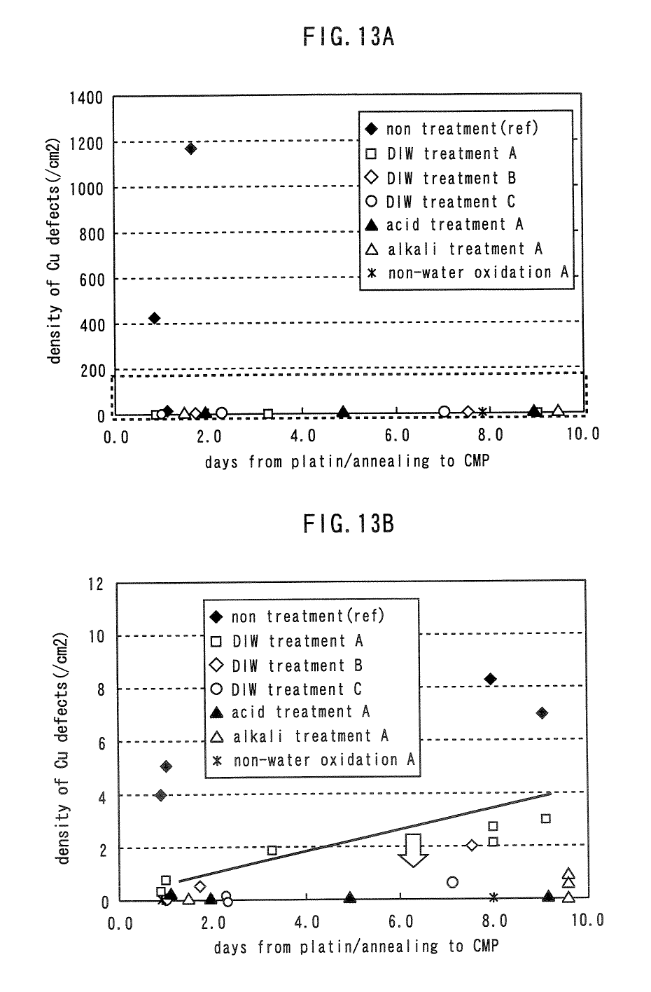

FIG. 13A is a graph showing densities of Cu defects prior to and after various pre-treatments in relation to the days from plating/annealing to CMP, and FIG. 13B is an enlarged graph of a portion surrounded by broken lines in FIG. 13A. From these figures, it has been found that with DIW treatment, the effect of inhibiting Cu defects lowers when storage is prolonged. This is considered for the reason that although the effect of removing water-soluble impurities is obtained, an effect of removing an insoluble oxide film such as a natural oxide film or the like is low. It has also been found that when the DIW treatment is carried out, storage control is effective after plating and annealing of a wafer to be treated. Especially, it has been found that when treatment with CO₂-dissolved water is used in combination with storage control, a more effective, low-cost and high Cu defect-inhibiting effect can be expected, thus such a treatment being a very effective one. On the other hand, it has been demonstrated that the three treatments such as the acid treatment, alkali treatment and non-aqueous treatment are all able to reduce a Cu defect density to substantially zero against wafers that has been subjected to storage more than or equal to 10 days. This leads to a conclusion that these treatments are a technique whose effect of removing a natural oxide is high. It is considered that the reason why a great variation is seen with respect to the Cu defect density of a non-treated wafer resides in the non-uniformity of surface conditions including a oxide film thickness of a plated and annealed wafer.

The Cu wiring formation method according to the fourth embodiment of the invention based on those results of the above described experiments is now described.

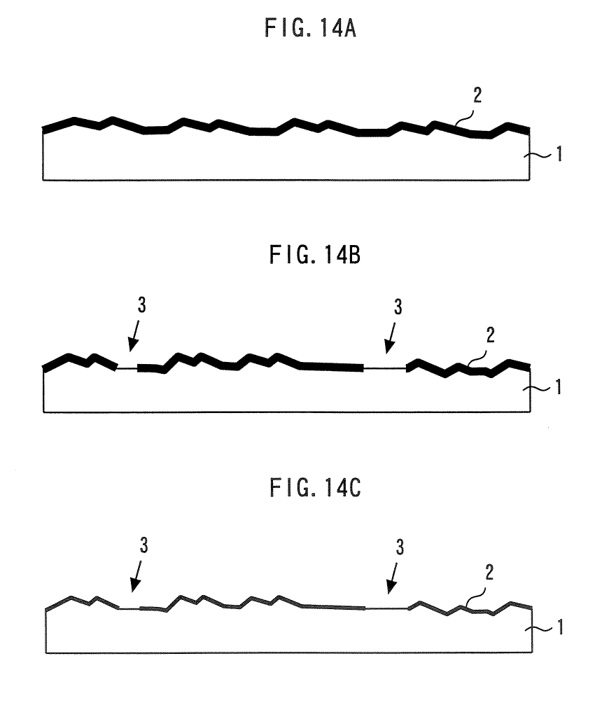

As shown in FIG. 14A, when the surface of a clean Cu film 1 is exposed to air, a uniform oxide film 2 having a thickness of several nm to several tens of nm is formed on the surface of the Cu film 1. Next, when the Cu film 1 is annealed at high temperatures, the thickness of the oxide film 2 becomes non-uniform as shown in FIG. 14B, thereby forming thin portions 3 in the oxide film 2. Thereafter, as shown in FIG. 14C, the oxide film 2 formed on the surface of the Cu film 1 is removed.

Such removal of the oxide film after annealing as set out above mitigates the non-uniformity of the oxide film and simultaneously removes impurities present in the oxide film. Accordingly, the occurrence of defects ascribed to local corrosion of the Cu film can be satisfactorily suppressed without need of any complicated steps at low costs.

The method of removing the oxide film may be that similar to removal of an oxide film prior to high-temperature annealing as described above. There is no need of completely removing the oxide film, and a reduced amount of the oxide results in the lowering of occurrence probability of defects.

The removal of the oxide film ensures not only an oxide film structure that is unlikely to cause local corrosion but also removal of soluble-impurities contained in the oxide film in the course of dissolution of the oxide film. When an aqueous solution is used for the removal of the oxide film, soluble impurities can be efficiently removed, thereby enhancing the effect of suppressing the occurrence of defects.

The removal of the oxide film after high-temperature annealing differs from the removal of the oxide film prior to high-temperature annealing. More particularly, if an oxidizing agent such as oxygen is contained in a solution, there is a risk that local corrosion occurs in the course of the removal of the oxide film. To avoid this, it is preferred to add an antioxidizing agent to the solution. For the antioxidizing agent, anticorrosives and reducing agents may be used. Where a reduced agent is used, an effect is obtained only by removing dissolved oxygen and thus, some effect can be attained by using it even in smaller amounts than in case where copper oxide is reduced.

It will be noted that in the oxide film, aside from oxide such as CuO, CuO₂ and the like, impurities caused by plating and other type of water-soluble and water-insoluble substances caused by contamination from outside exist. The oxide film formed after high-temperature annealing differs from a natural oxide film formed at normal temperatures in that minute distributions are formed with respect to the thickness and composition and various types of impurities are apt to be dissolved out. Accordingly, where water is deposited on the Cu film, local corrosion is liable to occur. Hence, in order to suppress the occurrence of local corrosion, such impurities contained in the oxide film may be removed by means of an aqueous solution. The aqueous solution used is preferably one that contains an antioxidizing agent. It will be noted that it takes along rinsing time before complete removal of the impurities to be dissolved out, which is not effective in practice. Accordingly, the removal of the oxide film is a practical and drastic solution.

### Fifth Embodiment

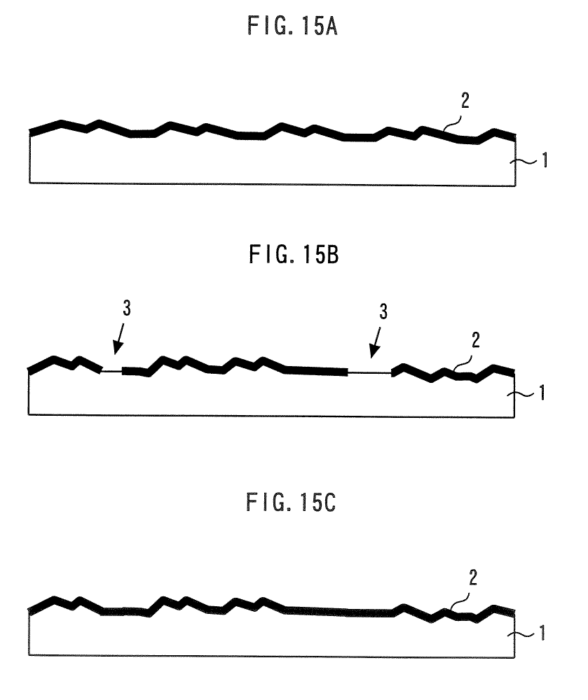

The Cu wiring formation method according to the fifth embodiment of the invention is described. As shown in FIG. 15A, when the surface of a clean Cu film 1 is exposed to air, a uniform oxide film 2 having a thickness of several nm to several tens of nm is formed on the surface of the Cu film 1. Next, the Cu film 1 is annealed at high temperatures, and the thickness of the oxide film 2 becomes non-uniform as shown in FIG. 15B to form thin portions 3 in the oxide film 2, thereby casing local corrosion to occur at the portions.

As shown in FIG. 15C, the surface of the Cu film 1 is oxidized in a non-aqueous environment (in a non-aqueous atmosphere). In this way, the portions are selectively oxidized to permit the oxide film to be uniform in thickness. Thus, the occurrence of defects ascribed to local corrosion of the Cu film can be satisfactorily suppressed without need of a complicated step at low costs.

The above oxidation step is carried out by heating under an atmospheric pressure or reduced pressure in an environment where oxygen exists. The heating temperature is preferably from 30° C. to 150° C. At temperatures lower than 30° C., it takes 10 hours or over before obtaining an effect of supplementing an oxide film, with the effect being not satisfactory. On the other hand, temperatures higher than 150° C. lead to too thick an oxide film, which undesirably takes a long polishing time in a subsequent CMP step. The heating time ranges from about several seconds to several tens of minutes. A high heating temperature ensures a heating effect within a shorter time.

In the oxidation step, the oxidation is preferably performed under conditions permitting a sputtering effect. This adds an effect of removing a non-uniform oxide film, thereby increasing an effect of suppressing the occurrence of defects. Moreover, a final thickness of the oxide film can be reduced, so that a polishing time in a subsequent CMP step can be shortened.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2005-327718, filed on Nov. 11, 2005 including specification, claims, drawings and summary, on which the Convention priority of the present application is based, are incorporated herein by reference in its entirety.

What is claimed is:

1. A Cu wiring formation method comprising the steps of:
forming a Cu film on a wafer by plating;
subjecting the Cu film to anticorrosive treatment on the surface thereof after the plating; and
annealing the Cu film after the anticorrosive treatment.

2. A Cu wiring formation method comprising the steps of:
forming a Cu film on a wafer by plating;
storing the wafer in anon-oxidative atmosphere after the plating; and
annealing the Cu film after the storage of the wafer in the non-oxidative atmosphere.

3. A Cu wiring formation method comprising the steps of:
forming a Cu film on a wafer by plating;
removing an oxide film formed on a surface of the Cu film after the plating; and
annealing the Cu film after the removal of the oxide film.

4. A Cu wiring formation method comprising the steps of:
forming a Cu film on a wafer by plating;
removing an oxide film formed on a surface of the Cu film after the plating;
subjecting the surface of the Cu film to anticorrosive treatment after the removal of the oxide film; and
annealing the Cu film after the anticorrosive treatment.

5. A Cu wiring formation method comprising the steps of:
forming a Cu film on a wafer by plating;
removing an oxide film formed on a surface of the Cu film after the plating;
storing the wafer in a non-oxidative atmosphere after the removal of the oxide film; and
annealing the Cu film after the storage of the wafer in the non-oxidative atmosphere.

6. A Cu wiring formation method comprising the steps of:
forming a Cu film on a wafer by plating;
annealing the Cu film after the plating; and
removing an oxide film formed on a surface of the Cu film after the annealing of the Cu film.

7. The Cu wiring formation method as defined in claim 6, wherein the oxide film is removed by means of an aqueous solution.

8. The Cu wiring formation method as defined in claim 7, wherein the aqueous solution contains an antioxidizing agent.

9. A Cu wiring formation method comprising the steps of:
forming a Cu film on a wafer by plating;
annealing the Cu film after the plating; and
removing an impurity present in an oxide film formed on a surface of the Cu film after the annealing of the Cu film.

10. The Cu wiring formation method as defined in claim 9, wherein the impurity is removed by means of an aqueous solution.

11. The Cu wiring formation method as defined in claim 10, wherein the aqueous solution contains an antioxidizing agent.

12. A Cu wiring formation method, comprising the steps of:
forming a Cu film on a wafer;
annealing the Cu film after the plating; and
oxidizing a surface of the Cu film in an non-aqueous environment after the annealing of the Cu film.
